(19) United States
(12) Patent Application Publication
(10) Pub. No.: US 2024/0385357 A1
(43) Pub. Date: Nov. 21, 2024

(54) RGB-IRP FILM GROUP AND PREPARATION PROCESS THEREFOR

(71) Applicant: ZHEJIANG MDK OPTICAL SEMICONDUCTOR CO., LTD., Jiaxing (CN)

(72) Inventors: CHING SHENG WENG, Jiaxing (CN); Gang WANG, Jiaxing (CN); Weihao YE, Jiaxing (CN)

(73) Assignee: ZHEJIANG MDK OPTICAL SEMICONDUCTOR CO., LTD., Jiaxing (CN)

(21) Appl. No.: 18/788,339

(22) Filed: Jul. 30, 2024

Related U.S. Application Data
(63) Continuation of application No. PCT/CN2024/078907, filed on Feb. 28, 2024.

(30) Foreign Application Priority Data
Mar. 9, 2023 (CN) 202310221995.3

(51) Int. Cl. G02B 5/22; G03F 7/00

(52) U.S. Cl. CPC G02B 5/223; G03F 7/0007

(57) ABSTRACT

An RGB-IRP film group and a preparation process therefor are provided. The preparation process includes the following recyclable links: performing adhesive coating, photoetching and development, film coating and adhesive removal, where the film coating is one or more film coating operations of an R film, a G film and a B film, and the adhesive coating is performed with a photoresist. According to the present disclosure, the transmittance of a film-coated product is doubled compared with the adoption of a (RGB-IRP) adhesive. Since a film-coating curve can be cut off for unnecessary wavebands, an IRC film or an IRC optical filter is not required. Furthermore, due to the large slope, the bandwidth can be enlarged, and the light flux can be effectively increased.

### CROSS REFERENCE TO THE RELATED APPLICATIONS

This application is a continuation application of International Application No. PCT/CN2024/078907, filed on Feb. 28, 2024, which is based upon and claims priority to Chinese Patent Application No. 202310221995.3, filed on Mar. 9, 2023, the entire contents of which are incorporated herein by reference.

### TECHNICAL FIELD

The present disclosure relates to the technical field of preparation of film groups, and in particular, to an RGB-IRP film group and a preparation process therefor.

### BACKGROUND

A yellow light preparation process is a process of protecting an underlayer by a part remained after exposure and development of a photosensitive substance (also referred to as a photoresist) coated on the surface of glass, then performing etching and stripping and finally obtaining a permanent pattern. For color filtering, a color layer of a common color optical filter mainly includes red, green and blue, and a displayed target color is achieved by combining red, green and blue pixel light-emitting areas with different brightness. Such patterned red, green and blue pixels are usually manufactured by a color photoresist.

Pigment is a common main component that provides color in the color photoresist. The pigment is mainly a pigment molecule aggregation having a unique chemical structure, is insoluble and is dispersed in a specific organic solvent in the form of small particles. The pigment-based color optical filter has generally low light transmittance and much stray light. After a (IRP+R+G+B) adhesive commonly used in the industry at present is patterned on glass, an IR part is cut off by coating IRC (or increasing the IRC optical filter) to reduce the stray light. FIG. 2 to FIG. 4 are the adhesive layer structure of the traditional solution and the light transmission detection results before and after IRC coating. The problems brought by the process are as follows:
(1) the comprehensive transmittance is low and generally about 30%-40%, but the index greatly affects the performance of the finished product.
(2) If IRC is plated, it is necessary to increase a whole yellow light film-coating process, the preparation process is complicated and has a long period, and the whole cost is increased by 25%. Furthermore, if an IRC optical filter is added, the thickness of the whole film group will be greatly increased, the thickness will be above 0.9 mm, and the cost will be increased.
(3) Since the glass substrate and IRC are inorganic materials, and RGB and IRP are organic materials, the combination reliability of the organic and inorganic materials will have a great hidden danger. If applied to a high-temperature or low-temperature environment, the materials are prone to cracking or film removal.

### SUMMARY

To overcome the shortcomings in the prior art, the present disclosure provides an RGB-IRP film group and a preparation process therefor. A film layer process is introduced in a yellow light preparation process, and a color photoresist is replaced with a conventional photoresist and by a film-coating process, so that the RGB-IRP film group with high light transmittance and clear cut-off can be obtained.

To achieve the above objective, the present disclosure provides a preparation process for an RGB-IRP film group, including at least one group of recyclable processes, where the recyclable process is performed on a glass substrate; adhesive coating, photoetching and development, film coating and adhesive removal are performed sequentially; the adhesive coating is performed with a photoresist; and the film coating is one or more film-coating operations of an R film, a G film, a B film or an IRP film.

Preferably, the circulation times of the recyclable processes are the same as the times of the film coating.

Preferably, the R film, the G film, the B film or the IRP film is in direct contact with the glass substrate.

Preferably, in the at least one group of recyclable processes, the same photoresist is used for the adhesive coating.

Preferably, a material of the film coating includes one or more of TIO₂, TA₂O₅, HFO₂, SIO₂ and AL₂O₃; and for a refractive index under a wavelength of 550 nm, a material with a high refractive index has a refractive index N of 1.9-2.5 and an absorptivity K of less than 0.1, and a material with a low refractive index has a refractive index N of less than 1.7 and an absorptivity K of less than 0.1.

Preferably, light-transmitting wavebands of the R film, the G film, the B film or the IRP film are respectively 400-500 nm, 500-600 nm, 600-710 nm and greater than 800 nm, the light transmittance of the R film, the G film, the B film or the IRP film reaches 95% or more, and the light-transmitting ranges are not crossed.

As another aspect of the present disclosure, the present disclosure provides an RGB-IRP film group, including a glass substrate, where the glass substrate is coated with one or more of the R film, the G film, the B film or the IRP film.

Preferably, the RGB-IRP film group does not include an IRC film and/or an IRC optical filter.

Preferably, the thickness is 0.6-0.8 mm, preferably, 0.755 mm, and the thickness of the R film, the G film, the B film or the IRP film is 3-6 um.

Preferably, the light-transmitting waveband of the IRP film is greater than 800 nm, and the light transmittance is kept unchanged with the extension of the waveband.

Beneficial effects of the present disclosure are as follows:
(1) the transmittance of the film-coated product is doubled compared with the adoption of a (RGB-IRP) adhesive.
(2) The film group of the present disclosure has extremely high transmittance, and a straight-up and straight-down curve can effectively increase the luminous flux, so that the final brightness can be improved. Furthermore, the vertical coordinate 0 represents cut-off, curve states corresponding to different film layers in the figure facilitate cut-off, and the curves are almost not crossed, that is, there is basically no optical cross area. Since a film-coating curve can be cut off for unnecessary wavebands, an IRC film or an IRC optical filter is not required, so that a yellow light film-coating process is saved, and the thickness after combination is effectively reduced. Furthermore, due to the large slope, the bandwidth can be enlarged, and the light flux can be effectively increased.
(3) There is a large customization space for the film-coating method. The bandwidth, the center wavelength, the cut-off depth and the transmittance can be customized according to requirements. Furthermore, the change efficiency is higher, and change can be completed in 1-2 days.

### BRIEF DESCRIPTION OF THE DRAWINGS

FIGS. 1A-1I are diagrams of specific steps of a process and film-coating change of a film group thereof according to an embodiment of the present disclosure, where FIG. 1A is adhesive coating, FIG. 1B is photoetching and development, FIG. 1C is G film coating, FIG. 1D is adhesive removal and remaining of the G film, FIG. 1E is adhesive coating, FIG. 1F is photoetching and development, FIG. 1G is R film coating, FIG. 1H is adhesive removal, and FIG. 1I is repetition of the steps until a B film and an IRP film are coated;

FIG. 2 is a schematic diagram of an adhesive structure combination according to a traditional solution;

FIG. 3 is an RGB transmittance detection result when an adhesive layer structure of the traditional solution is not coated with IRC;

FIG. 4 is an RGB transmittance detection result after an adhesive layer structure of the traditional solution is coated with IRC;

FIG. 5 is a schematic diagram of a film layer structure combination according to the solution of the present disclosure; and

FIG. 6 is an RGB transmittance detection result of a film layer structure according to the solution of the present disclosure.

### DETAILED DESCRIPTION OF THE EMBODIMENTS

To better describe the objectives, the technical solutions and the advantages of the present disclosure, the present application is further described below with reference to specific embodiments.

### Embodiment 1

The process of this embodiment includes the following recyclable links:
adhesive coating—photoetching and development—G/R/B film coating—adhesive removal (the G/R/B film is respectively remained).

The process links are taken as a cycle unit, and the cycle process is performed many times according to the film layer structure and the number of layers involved.

The specific situation of each process link is as follows:
adhesive coating: a color adhesive was replaced with a conventional photoresist (a negative photoresist which can resist high temperature and is nearly colorless and slightly yellowish) for adhesive coating.
photoetching and development: photoetching and development were performed at a preset position to remove part of the photoresist. This is a yellow light part of the process, which is mainly used to leave a space for film coating, as shown in an empty position on the substrate in the figure. This is significantly different from the traditional process in which the color adhesive is remained at the corresponding position. An adhesive area left after the conventional photoetching and development is just opposite to an adhesive area left after the photoetching and development in this step. Furthermore, the photoresist in this step reserves a vacancy for the film-coating area, and the photoresist at the other position is also used to bear the coated film. The coated films at the redundant parts are removed during adhesive removal.
R/G/B film coating: film-coating operation was performed sequentially according to the film layer design and the types of the required coated films, and one of the R film, the G film and the B film was selected for film coating, where the sequence of the types of the coated films does not affect the product.
Adhesive removal: removing the conventional photoresist.

The process links are taken as a cycle unit, and the cycle process is performed many times according to the film layer structure and the number of layers involved. The joint of the films can be covered with a black film. According to the present disclosure, the color adhesive is replaced with the conventional adhesive, so that one yellow light film-coating process is saved, and the thickness after combination is effectively reduced. The transmittance of the film-coated product is doubled compared with the adoption of the (RGB-IRP) adhesive, that is, the height of the highest point in the figure is significantly increased, and the light-transmitting area under the curve peak is increased more significantly. Since a film-coating curve can be cut off for unnecessary wavebands, an IRC film or an IRC optical filter is not required. Furthermore, due to the large slope, the bandwidth can be enlarged, and the light flux can be effectively increased.

According to the present invention, there is a large customization space for the film-coating method. The bandwidth, the center wavelength, the cut-off depth and the transmittance can be customized according to requirements. Furthermore, the change efficiency is higher, and change can be completed in 1-2 days.

### Embodiment 2

The process of this embodiment includes the following recyclable links:
adhesive coating—photoetching and development—R/G/B film coating—adhesive removal (the R/G/B film is respectively remained).

The process links are taken as a cycle unit, and the cycle process is performed many times according to the film layer structure and the number of layers involved.

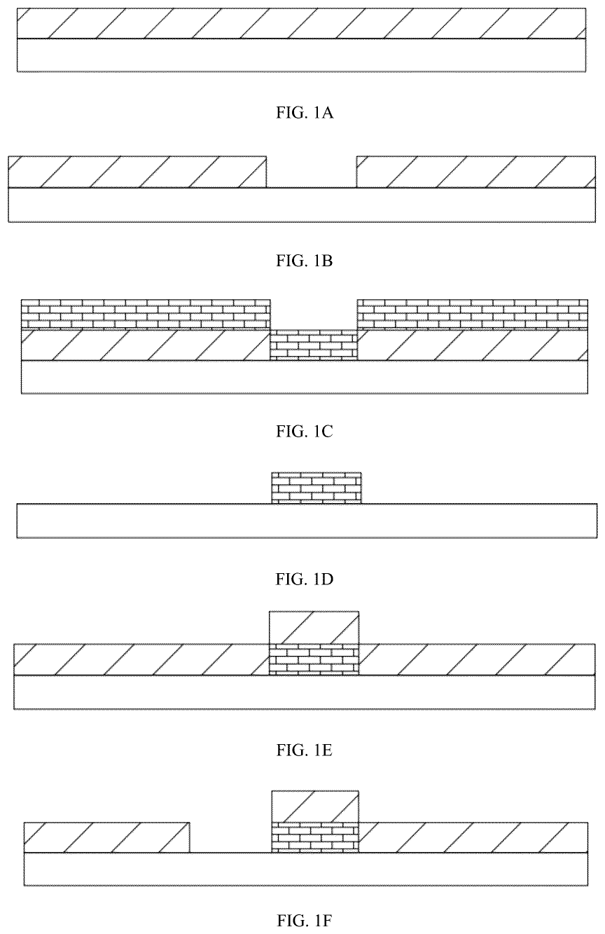

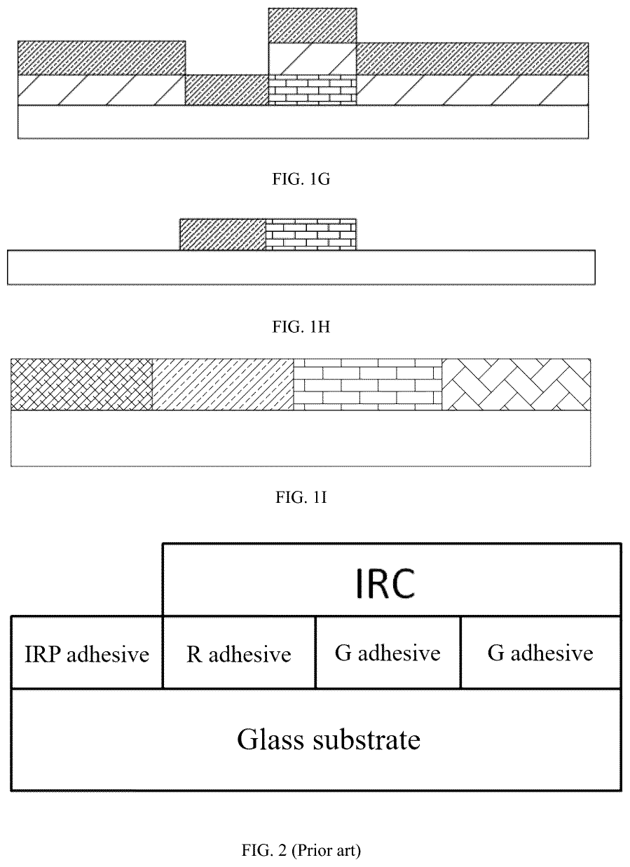

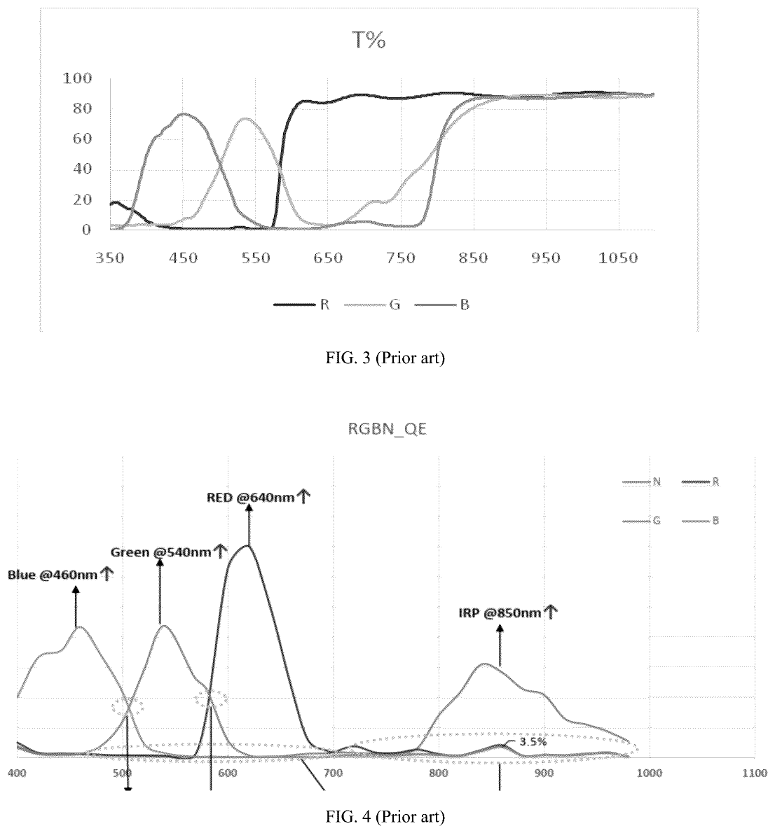

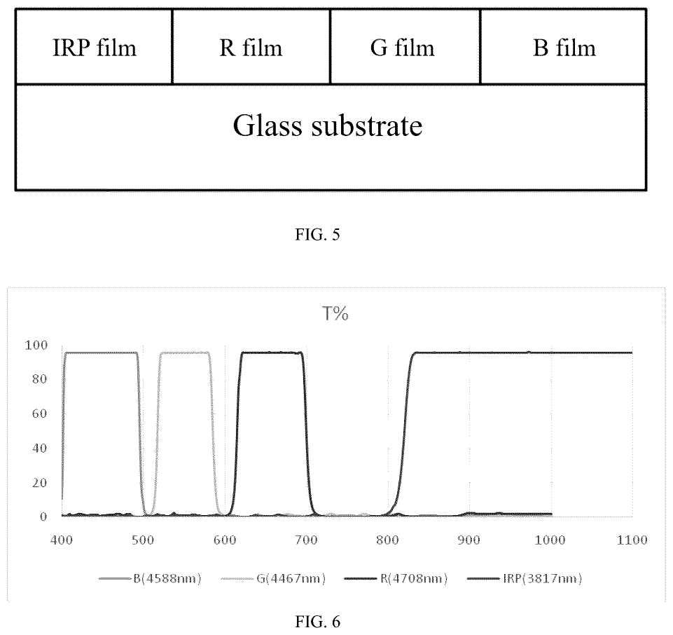

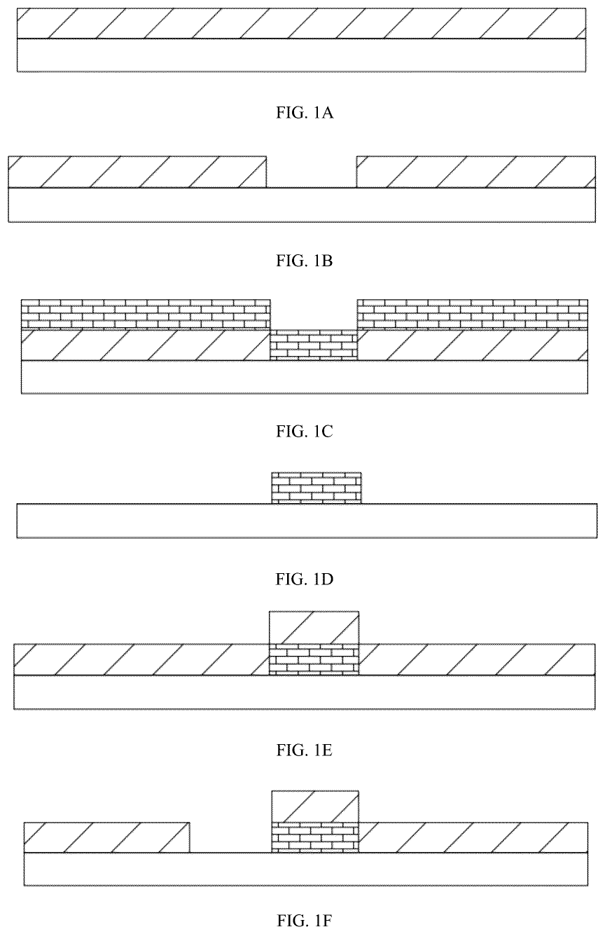

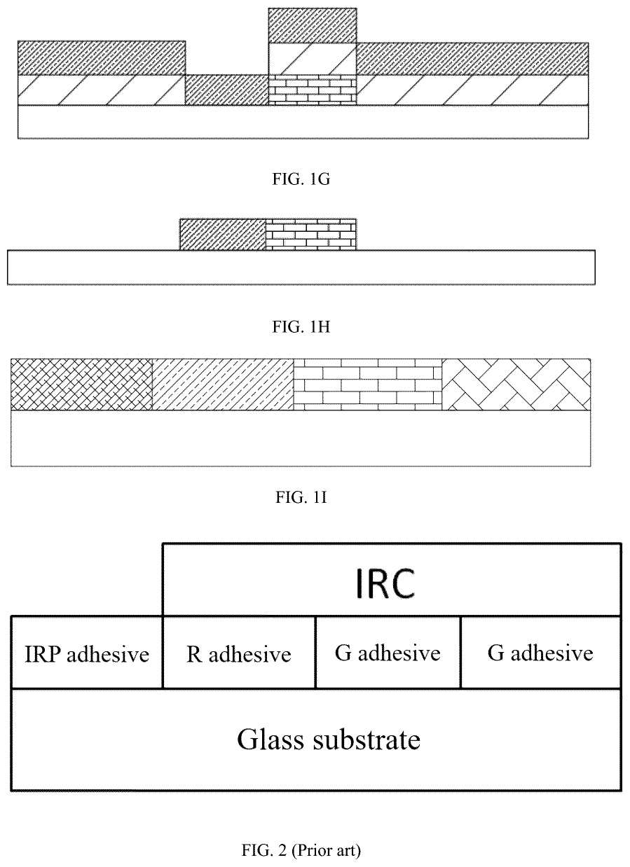

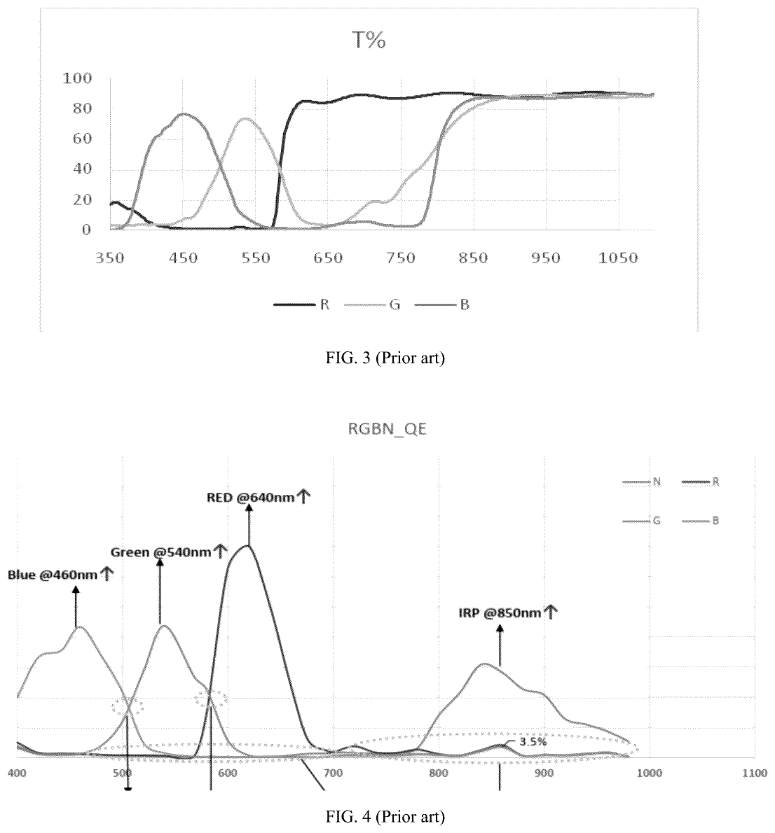

The specific situation of each process link is as follows:
adhesive coating: as shown in FIG. 1A, the surface of a substrate was coated with a photoresist with a thickness of 6-15 um, a specific temperature and time were set by a heat plate for roasting, and the photoresist was dried.
Photoetching and development: as shown in FIG. 1B, specific energy and focus were set by a stepped photoetching machine for photoetching, overhanging development was used to coat developing liquid for 5-10 minutes to form a pattern, the photoresist at an area to be coated was removed to expose the substrate, and the photoresist at an area without coating was remained.
G film coating: as shown in FIG. 1C, an evaporator or a sputtering machine was used for film coating based on the previous step, where the film-coating temperature is 100° C.-250° C., and the thickness of the process film is controlled to 3-6 um. During film coating, the corresponding film-coating material was selected according to the G film. The common film-coating material is TIO2/TA2O5/HFO2/SIO2/AL2O3, where for a refractive index under a wavelength of 550 nm, a material with a high refractive index has a refractive index N of 1.9-2.5 and an absorptivity K of less than 0.1, and a material with a low refractive index has a refractive index N of less than 1.7 and an absorptivity K of less than 0.1.
Adhesive removal: as shown in FIG. 1D, adhesive removal was performed by a tank soaking type device, the photoresist and the G film on the photoresist were removed, and only the G film coated on the substrate was remained.

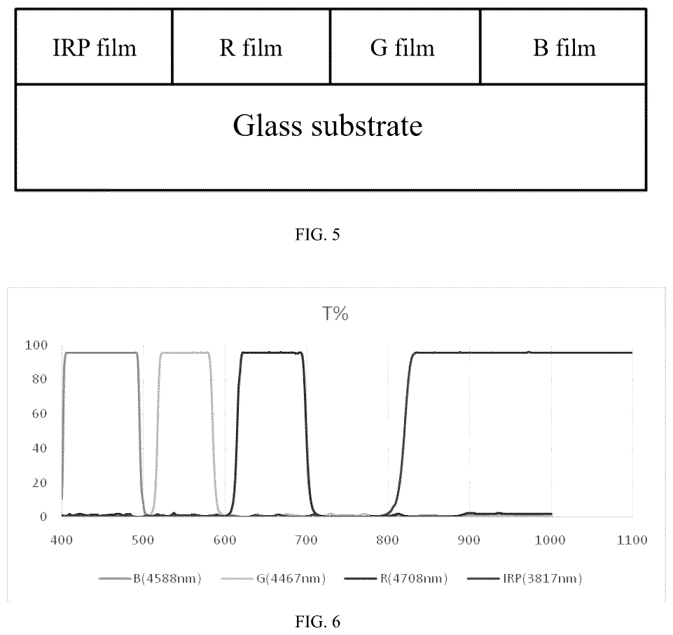

The cyclic coating of the R film was repeated, as shown in FIG. 1E to FIG. 1H, adhesive coating, photoetching and development, R film coating and adhesive removal were performed, the cyclic coating of the R film was repeated again, as shown in FIG. 1I, and the IPR film was coated finally to form the RGB-IRP film group structure as shown in FIG. 5.

The structure was subjected to RGB transmittance detection. The result is shown in FIG. 6.

Finally, it should be noted that the above embodiments are only used to describe the technical solutions of the present disclosure, but not to limit the protection scope of the present disclosure. Although the present disclosure is described in detail with reference to the preferred embodiments, those of ordinary skill in the art should understand that modification or equivalent substitution may be made on the technical solutions of the present disclosure without departing from the spirit scope of the technical solutions of the present disclosure.

What is claimed is:

1. A preparation process for an RGB-IRP film group, comprising performing at least one group of recyclable processes on a glass substrate; wherein the at least one group of recyclable processes comprises adhesive coating, photoetching and development, film coating, and adhesive removal sequentially; the adhesive coating is performed with a photoresist; and the film coating is one or more film coating operations of an R film, a G film, a B film, or an IRP film.

2. The preparation process for the RGB-IRP film group according to claim 1, wherein circulation times of the at least one group of recyclable processes are the same as times of the film coating.

3. The preparation process for the RGB-IRP film group according to claim 1, wherein the R film, the G film, the B film, or the IRP film is in a direct contact with the glass substrate.

4. The preparation process for the RGB-IRP film group according to claim 1, wherein in the at least one group of recyclable processes, a same photoresist is used for the adhesive coating.

5. The preparation process for the RGB-IRP film group according to claim 1, wherein a material for the film coating comprises one or more of TIO₂, TA₂O₅, HFO₂, SIO₂, and AL₂O₃; and for a refractive index under a wavelength of 550 nm, a material with a high refractive index has a refractive index N of 1.9-2.5 and an absorptivity K of less than 0.1, and a material with a low refractive index has a refractive index N of less than 1.7 and an absorptivity K of less than 0.1.

6. The preparation process for the RGB-IRP film group according to claim 1, wherein light-transmitting wavebands of the R film, the G film, the B film, or the IRP film are respectively 400-500 nm, 500-600 nm, 600-710 nm, and greater than 800 nm, light-transmitting ranges are not crossed, and a light transmittance reaches 95% or more.

7. An RGB-IRP film group prepared by the preparation process for the RGB-IRP film group according to claim 1, comprising the glass substrate, wherein the glass substrate is coated with one or more of the R film, the G film, the B film, or the IRP film.

8. The RGB-IRP film group according to claim 7, wherein the RGB-IRP film group does not comprises an IRC film and/or an IRC optical filter.

9. The RGB-IRP film group according to claim 7, wherein a thickness of the RGB-IRP film group is 0.6-0.8 mm.

10. The RGB-IRP film group according to claim 7, wherein a light-transmitting waveband of the IRP film is greater than 800 nm, and a light transmittance is kept unchanged with an extension of the light-transmitting waveband.

11. The RGB-IRP film group according to claim 7, wherein in the preparation process, circulation times of the at least one group of recyclable processes are the same as times of the film coating.

12. The RGB-IRP film group according to claim 7, wherein the R film, the G film, the B film, or the IRP film is in a direct contact with the glass substrate.

13. The RGB-IRP film group according to claim 7, wherein in the at least one group of recyclable processes of the preparation process, a same photoresist is used for the adhesive coating.

14. The RGB-IRP film group according to claim 7, wherein in the preparation process, a material for the film coating comprises one or more of TIO₂, TA₂O₅, HFO₂, SIO₂, and AL₂O₃; and for a refractive index under a wavelength of 550 nm, a material with a high refractive index has a refractive index N of 1.9-2.5 and an absorptivity K of less than 0.1, and a material with a low refractive index has a refractive index N of less than 1.7 and an absorptivity K of less than 0.1.

15. The RGB-IRP film group according to claim 7, wherein light-transmitting wavebands of the R film, the G film, the B film, or the IRP film are respectively 400-500 nm, 500-600 nm, 600-710 nm, and greater than 800 nm, light-transmitting ranges are not crossed, and a light transmittance reaches 95% or more.
